(19) United States
(12) Patent Application Publication
(10) Pub. No.: US 2011/0048529 A1
(43) Pub. Date: Mar. 3, 2011

(54) SOLAR CELL

(75) Inventors: Doo-Youl Lee, Seoul (KR); Dong-Seop Kim, Seoul (KR); Jin-Wook Lee, Suwon-si (KR); Hwa-Young Ko, Seoul (KR)

(73) Assignee: SAMSUNG ELECTRONICS CO., LTD., Suwon-si (KR)

(21) Appl. No.: 12/828,588

(22) Filed: Jul. 1, 2010

(30) Foreign Application Priority Data
Sep. 3, 2009 (KR) 10-2009-0083143

(51) Int. Cl. H01L 31/0236; H01L 31/0256

(52) U.S. Cl. 136/256; 136/261

(57) ABSTRACT

A solar cell includes a semiconductor substrate having a plurality of contact holes penetrating therethrough, from one surface to the opposing surface and including a part having a first conductive layer selected from p-type and n-type and a part having a second conductive layer different from the first conductive layer and selected from p-type and n-type semiconductor, a first electrode formed on one surface of the semiconductor substrate and electrically connected with the part having the first conductive layer, a second electrode formed on the other surface of the semiconductor substrate and electrically connected with the first electrode, and a third electrode formed on the same surface as in the second electrode and electrically connected with the part having the second conductive layer of the semiconductor substrate, wherein the plurality of contact holes form a contact hole group, and the first electrode and the second electrode are connected through one or more of the plurality of contact holes of the contact hole group.

This application claims priority to Korean Patent Application No. 10-2009-0083143 filed on Sep. 3, 2009, and all the benefits accruing therefrom under 35 U.S.C. 119, the contents of which are herein incorporated by reference in its entirety.

### BACKGROUND OF THE INVENTION

1. Field of the Invention

This disclosure relates to a solar cell.

2. Description of the Related Art

A solar cell is a photoelectric conversion device that transforms solar energy into electrical energy. Such technology has garnered much attention as an infinite pollution-free next generation energy resource.

A typical solar cell includes a semiconductor substrate including p-type and n-type semiconductors, and electrodes positioned over or under the semiconductor substrate. A solar cell produces electrical energy when an electron-hole pair (“EHP”) is produced in a photoactive layer between the p-type and n-type semiconductors when solar light energy is absorbed by the photoactive layer, transferring the electrons and holes so produced to the n-type and p-type semiconductors, respectively, and then collecting the electrons and holes in each electrode.

However, where improved solar cell performance is needed, it is important to increase the efficiency of solar cells in order to generate as much electrical energy as possible. Solar cells having various structures have been researched to increase the efficiency thereof. It is also important to decrease process failures in the research on solar cells having various structures.

### BRIEF SUMMARY OF THE INVENTION

In an embodiment, a solar cell with improved efficiency and decreased process failures is provided.

According to one aspect, provided is a solar cell that includes a semiconductor substrate having a plurality of contact holes penetrating from one surface to the other surface and including a part having a first conductive layer selected from p-type and n-type conductive layers and a part having a second conductive layer different from the first conductive layer and selected from p-type and n-type conductive layers, a first electrode formed on one surface of the semiconductor substrate and electrically connected with the part having the first conductive layer, a second electrode formed on the other surface of the semiconductor substrate and electrically connected with the first electrode, and a third electrode formed on the same surface as in the second electrode and electrically connected with the part having the second conductive layer of the semiconductor substrate, wherein the plurality of contact holes are proximally arranged to provide a contact hole group, and the first electrode and the second electrode are connected through one or more of the plurality of contact holes of the contact hole group.

The contact hole groups may be arranged in a matrix shape.

The first electrode may include a part that is arranged in parallel with a part of an adjacent first electrode, and a converged part that converges with the adjacent first electrodes.

The first electrode may contact the second electrode at the converged part.

The converged part of the first electrode may overlap with one or more of the plurality of contact holes of a portion of a plurality of the contact hole groups.

The converged parts of a plurality of the first electrodes may converge with a plurality of adjacent first electrodes.

The second electrode may fill in at least a portion of contact holes of the contact hole group.

The second electrode may include a bar part extending along one direction of a plane of the substrate, and a plurality of contact hole groups may be arranged to overlap with the bar part of the second electrode.

The solar cell may further include a dielectric layer disposed between opposing surfaces of the semiconductor substrate and the second electrode and third electrode and may have a plurality of openings therethrough, and the semiconductor substrate may be electrically connected with the third electrode through the openings.

The dielectric layer may be disposed between the semiconductor substrate and the second electrode in the contact hole.

Even if the contact holes and a front electrode for collecting electrons are misaligned, the front electrode may contact a bus bar electrode formed on the rear surface of the semiconductor substrate since the contact holes are grouped in the contact hole group.

In another embodiment, a solar cell includes a semiconductor substrate having a plurality of contact holes penetrating from one surface to an opposing surface of the semiconductor substrate and having a part having a first conductive layer selected from p-type and n-type conductive layers and a part having a second conductive layer different from the first conductive layer and selected from a p-type conductive layer and an n-type conductive layer; a first electrode formed on one surface of the semiconductor substrate and electrically connected with the part having the first conductive layer; a second electrode formed on an opposing surface of the semiconductor substrate and electrically connected with the first electrode; and a third electrode formed on the surface of the semiconductor substrate having the second electrode and electrically connected with the part having the second conductive layer of the semiconductor substrate, wherein the plurality of contact holes form a contact hole group, and the first electrode and the second electrode are connected through one or more contact holes of a portion of a plurality of contact hole groups, wherein the connected first and second electrodes form where the first electrode and the contact hole group matrix are misaligned.

### BRIEF DESCRIPTION OF THE DRAWINGS

FIG. 1 is a top plan view showing a front surface of an exemplary solar cell according to one embodiment.

FIG. 2 is a top plan view showing a rear surface of an exemplary solar cell according to one embodiment.

FIG. 3 is a cross-sectional view of the exemplary solar cell of FIG. 1 and FIG. 2 taken along the III-III line.

FIG. 4 is a cross-sectional view of the exemplary solar cell of FIG. 1 and FIG. 2 taken along the IV-IV line.

FIGS. 5 and 6 are views showing cross-sections of exemplary solar cells according to another embodiment.

FIGS. 7 and 8 show misalignment between electrodes and contact holes of a semiconductor substrate of the exemplary solar cell due to slanting front electrodes.

### DETAILED DESCRIPTION OF THE INVENTION

Exemplary embodiments of this disclosure will hereinafter be described in detail referring to the following accompanied drawings, and can be easily performed by those who have common knowledge in the related field. However, these embodiments are only exemplary, and this disclosure is not limited thereto.

As used herein, the terms “a” and “an” are open terms that may be used in conjunction with singular items or with plural items. It will be further understood that the terms “comprises” and/or “comprising,” when used in this specification, specify the presence of stated features, regions, integers, steps, operations, elements, and/or components, but do not preclude the presence or addition of one or more other features, regions, integers, steps, operations, elements, components, and/or groups thereof. All ranges and endpoints reciting the same feature are independently combinable.

As used herein, the term “and/or” includes any and all combinations of one or more of the associated listed items.

In the drawings, the thickness of layers, films, panels, regions, and the like, are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Furthermore, relative terms, such as “lower”, “under” or “bottom”, “upper” “over” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. As used herein, the terms “front” and “rear”, with respect to the solar cell, are not relative terms but distinguish between the surface exposed to incident sunlight to generate electricity (“front”), and a surface not generating electricity when exposed to sunlight (“rear”), unless otherwise specified.

It will be understood that, although the terms first, second, third, and the like. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

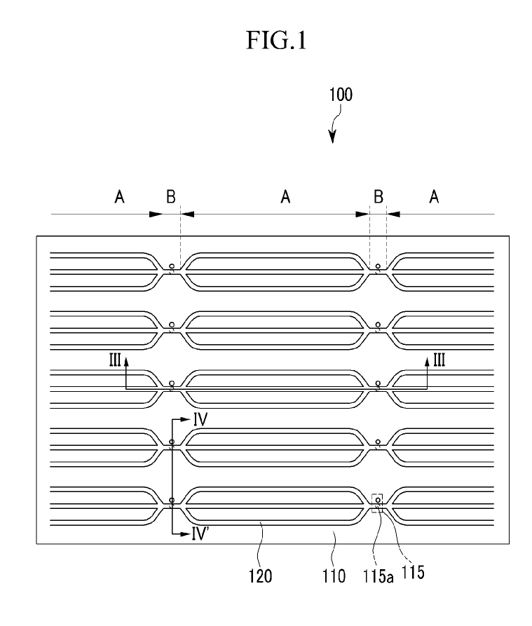

Referring FIGS. 1 to 3, the solar cell according to one embodiment is described.

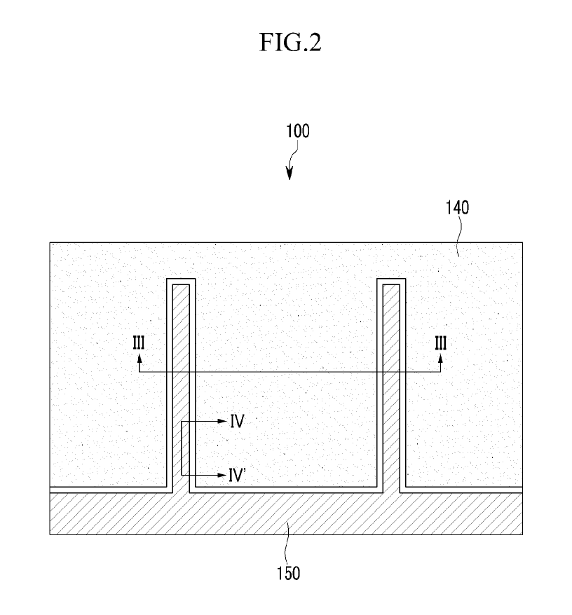

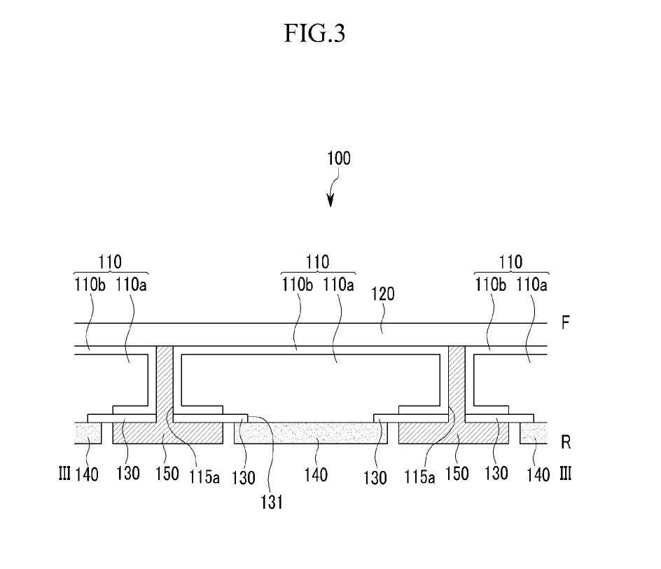

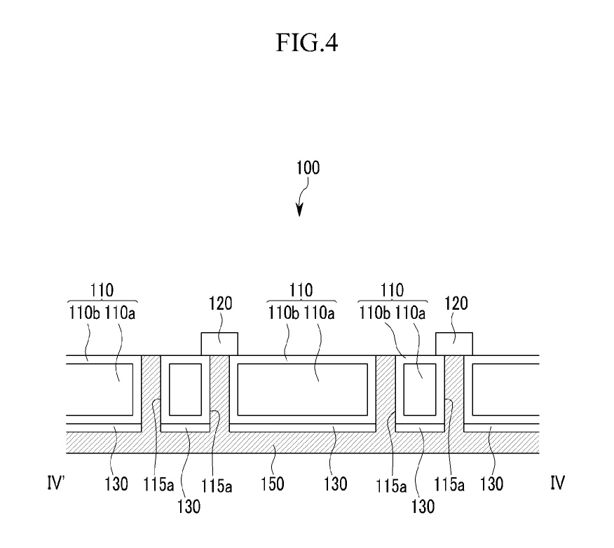

FIG. 1 is a top plan view showing a front surface of a solar cell according to one embodiment, FIG. 2 is a top plan view showing a rear surface of a solar cell according to one embodiment, FIG. 3 is a cross-sectional view of a solar cell of FIG. 1 and FIG. 2 taken along the III-III line, and FIG. 4 is a cross-sectional view of a solar cell of FIG. 1 and FIG. 2 taken along the IV-IV′ line. It will be understood that the cross-section along lines III-III and IV-IV′ in the front view in FIG. 1 correspond to the cross-section taken along lines III-III and IV-IV′ respectively in the rear view of FIG. 2.

Hereinafter, for better understanding and ease of description, in the center of one surface of a semiconductor substrate 110, a front surface, a rear surface, and upper and lower parts are described for the relationship, but the relationship may be changed depending upon the viewing direction.

According to one aspect, a solar cell 100 includes a semiconductor substrate 110. The semiconductor substrate 110 may be formed of crystalline silicon or a compound semiconductor such as an alloyed silicon, strained silicon, or a multilayered or multi-regioned silicon substrate. In the case of crystalline silicon, as an example, the semiconductor substrate 110 may include a silicon wafer.

As shown in FIG. 3, the semiconductor substrate 110 includes a first semiconductor layer 110a and a second semiconductor layer 110b disposed on one or more surfaces of and surrounding the first semiconductor layer 110a. One of the first semiconductor layer 110a and the second semiconductor layer 110b is a semiconductor layer doped with a p-type impurity, and the other is a semiconductor layer doped with an n-type impurity. For example, the first semiconductor layer 110a may be a p-type semiconductor layer and the second semiconductor layer 110b may be an n-type semiconductor layer. In an embodiment, the p-type impurity may be a Group III element such as boron (B), and the n-type impurity may be a Group V element such as phosphorus (P).

The semiconductor substrate 110 has a plurality of contact holes 115a penetrating the substrate 110 from the front surface (F) to the rear surface (R).

Referring to FIG. 1, a plurality of contact holes 115a are arranged proximally in a predetermined position to provide a contact hole group 115. As disclosed herein, “plurality” refers to two or more. The plurality of contact holes 115a may be arranged in any suitable pattern, such as regularly or intervally spaced along a straight line, crossed straight lines, circular patterns, or arranged in a cluster of any geometric pattern as desired, such as three contact holes 115a arranged in a triangular pattern, four contact holes 115a arranged in a square or diamond pattern, or the like, or a combination, where each contact hole 115a forms a vertex of the pattern used. More than one pattern may be used. The contact hole groups 115 are themselves arranged in a matrix shape along with a vertical column and a horizontal row. The vertical column and horizontal row may be at right angles to one another, may be angled with respect to one another, and may form alternating angled rows. In an embodiment, the vertical column and horizontal rows are at right angles to one another. In another embodiment, the vertical column and horizontal rows are slanted. As used herein, “slanted” means having an angle of less than 90 degrees relative to an intersecting line.

Each of the plurality of contact hole groups includes a plurality of contact holes 115a, and the contact hole groups are spaced apart by a first predetermined distance. In addition, each of the contact hole 115a of each contact hole group 115 are also spaced apart by a second predetermined distance, where the second predetermined distance is greater than the first predetermined distance. FIG. 1 illustrates the example that each contact hole group 115 includes two contact holes 115a, but it will be understood that the disclosure is not limited thereto and may include various numbers of contact holes.

The surface of the semiconductor substrate 110 may be textured. In an exemplary embodiment, the front surface of the semiconductor substrate shown in FIG. 1, which receives incident sunlight, may be textured. The surface-textured semiconductor substrate 110 may in this way have a porous structure such as a honeycomb pattern with pores oriented vertical to the plane of the substrate and passing between substrate surfaces, or only partially into a surface of the surface-textured semiconductor substrate 110 for a predetermined distance, or may have pyramid-shaped protrusions and depressions. The surface-textured semiconductor substrate 110 increases the light absorption by increasing the surface area of the semiconductor substrate 110, and further increasing the efficiency of the solar cell by decreasing reflectivity.

A plurality of front electrodes 120 is formed on a surface of the semiconductor substrate 110 to contact with the second semiconductor layer 110b. The front electrode 120 extends along one direction of and in the plane of the semiconductor substrate 110, and a part of the front electrode 120 overlaps with one or more contact holes 115a of the contact hole group 115. As used herein “overlaps” means at least partially positioned over when viewed along the vertical direction, at right angles to the plane of the semiconductor substrate 100.

Referring to FIG. 1, the front surface of the solar cell 100 includes a part A where a plurality of parts of front electrodes 120 are arranged in parallel and a part B where the plurality of parts of the front electrodes 120 converge with adjacent parts of front electrodes 120. The part B where the front electrodes 120 converge overlaps with one or more contact holes 115a of the contact hole group 115.

FIG. 1 illustrates, as an example, that in part A three parts of front electrode 120 converge, but it will be appreciated that the number and shape of parts of the front electrodes in part A is not limited thereto, and the number and shape may thus be varied. For example, the shape in part A of the front electrode 120 may be straight lines as shown, or may be parallel wavy lines, parallel zigzag lines, parallel crenellated lines, parallel lines of varying width, or the like; and may vary in number from a single line, two lines, three lines as shown in FIG. 1, or more than three lines without limitation provided the desired advantages of the arrangement of the parts A of the electrode are preserved.

The front electrodes 120 may be formed of a low-resistance metal such as silver (Ag) or an alloy thereof, and are designed in a grid pattern to decrease shadowing loss and sheet resistance.

An insulation layer (not shown) may be formed as an anti-reflective coating (“ARC”) between opposing surfaces of the front electrode 120 and the semiconductor substrate 110 to decrease reflectivity and to increase selectivity of a predetermined wavelength region, where the anti-reflective coating may contain a chromophore absorbing in a preselected wavelength of the spectrum of incident light, and/or may by varying thickness prevent a preselected wavelength from being reflected.

A dielectric layer 130 is formed on the rear surface of the semiconductor substrate 110. The dielectric layer 130 may have a contact hole 131 exposing a surface of the first semiconductor layer 110a on the rear surface of the semiconductor substrate 110, and the rear electrode 140 may contact the semiconductor substrate 110 through the contact hole 131.

The dielectric layer 130 may include one selected from the group consisting of aluminum oxide (Al₂O₃), aluminum nitride (AlN), aluminum oxynitride (AlON), and combinations thereof, and may have a thickness of about 30 to about 1000 Å.

In the drawings, the dielectric layer 130 is illustrated as a monolayer, but it is not limited thereto and may alternatively or in addition be formed as two or more layers.

Under the dielectric layer 130, the rear electrode 140 and a bus bar electrode 150 are separately formed. As shown in FIG. 2, the bus bar electrode 150 includes a horizontally-extended part (i.e., in the plane of the substrate) and a vertically-extended part (i.e., at right angles to the plane of the substrate), and the rear electrode 140 is formed on the lower surface (i.e., rear surface, as shown) of the semiconductor substrate 110 where the bus bar electrode 150 is not formed. However, the positions of the rear electrode 140 and the bus bar electrode 150 may be varied.

The rear electrode 140 contacts the first semiconductor layer 110a. The rear electrode 140 may be formed of an opaque metal such as aluminum (Al), and may have a thickness of about 2 to about 50 μm.

When the rear electrode 140 made of the metal such as aluminum contacts the silicon of the first semiconductor layer 110a, the aluminum functions as a p-type impurity, and an internal electromagnetic field is generated which prevent electrons generated in the semiconductor substrate 110 from transferring to the rear surface of the semiconductor substrate 110. Accordingly, the internal electromagnetic field prevents the separated charges from being re-combined and eliminated on the rear surface of the semiconductor substrate 110, thereby increasing efficiency of the solar cell.

The bus bar electrode 150 is electrically connected to the front electrode 120 through a contact hole 115a. The bus bar electrode 150 connected to the front electrode 120 is formed on the rear surface of the semiconductor substrate 110, so the area occupied by metal on the front surface of the semiconductor substrate 110 is decreased to maximize the surface area of the front surface that may be exposed to sunlight and thereby reduce shadowing loss and increase efficiency of the solar cell.

The bus bar electrode 150 is longitudinally formed on the rear surface of the semiconductor substrate 110 along the direction that the plurality of contact hole groups 115 are arranged, and fills in (i.e., metalizes) all the contact holes 115a of each contact hole group 115. FIG. 4 shows that the bus bar electrode 150 fills in all the contact holes 115a as an example, but it is not limited thereto, and the bus bar electrode 150 may fill in one or more of the contact holes 115a for each contact hole group 115.

The bus bar electrode 150 contacts the converged part B of the adjacent front electrode 120 through at least one of the contact holes 115a of at least a portion of the contact hole group 115.

According to one embodiment, since a plurality of contact holes 115a are arranged proximally to one another to provide a contact hole group 115, the contact between the front electrode 120 and the bus bar electrode 150 is satisfactorily maintained even when the front electrode 120 and contact holes 115a of the semiconductor substrate 110 are misaligned. It will be appreciated that “misalignment” and “misaligned” as used herein means not aligned along the grid lines of a matrix of the contact hole groups 115 within a reasonable tolerance such that the part B of the front electrode 120 still overlaps one or more contact holes 115a of at least a portion of the plurality of contact hole groups 115 in the matrix, so that electrical connectivity with the bus bar electrode 150 is established. Thus in an embodiment, the front electrode 120 and the bus bar electrode 150 are connected through one or more contact holes of a portion of a plurality of contact hole groups and the connections form where the first electrode and a matrix of the contact hole groups 115 are misaligned.

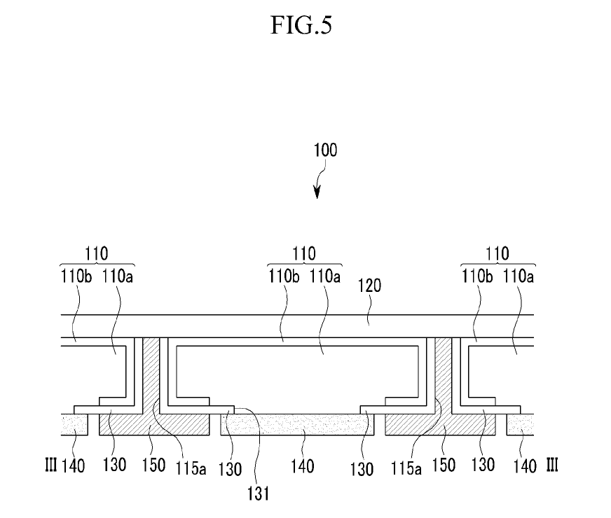

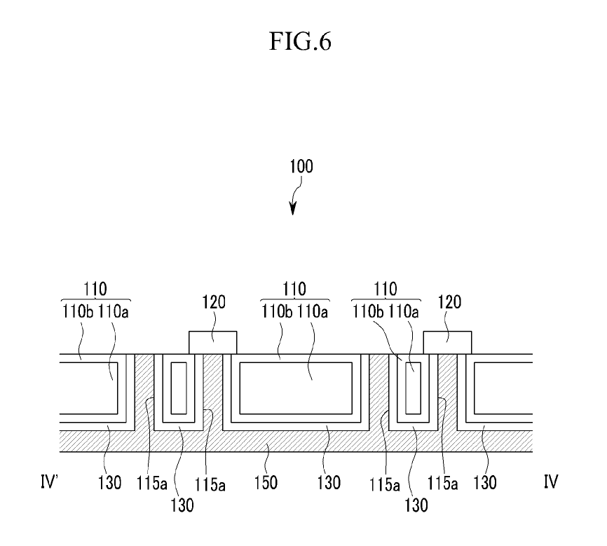

FIGS. 5 and 6 are views showing cross-sections of solar cells of FIGS. 1 and 2, along lines III-III and IV-IV', respectively, according to another embodiment.

The solar cells according to this embodiment have almost the same structure as in the above-described embodiment illustrated in cross-section in FIGS. 3 and 4, except that the dielectric layer 130 is formed on the rear surface and the side surface of the semiconductor substrate 110, to surround contact holes 115a in the contact hole group 115.

When the contact holes 115a are formed in the semiconductor substrate 110, the semiconductor substrate 110 around the contact hole group 115 may be damaged, so the charges generated during operation of the solar cell may be transferred through the damaged part to generate a shunt current. In addition, the charges may recombine with the charges carried by the metal of the bus bar electrode 150 and eliminated. The inclusion of dielectric layer 130 on the rear and side surfaces of the semiconductor substrate 110 (i.e., on the inner side surfaces of contact holes 115a) prevents the transfer of charges through the damaged part of the semiconductor substrate 110 to an electrode, such as the bus bar electrode 150, by a fixed charge formed on the surface thereof, so that it is possible to decrease the electrical loss that may be caused by the shunt current by maintaining electrical separation of the charges, thereby preventing the charges from being recombined and eliminated.

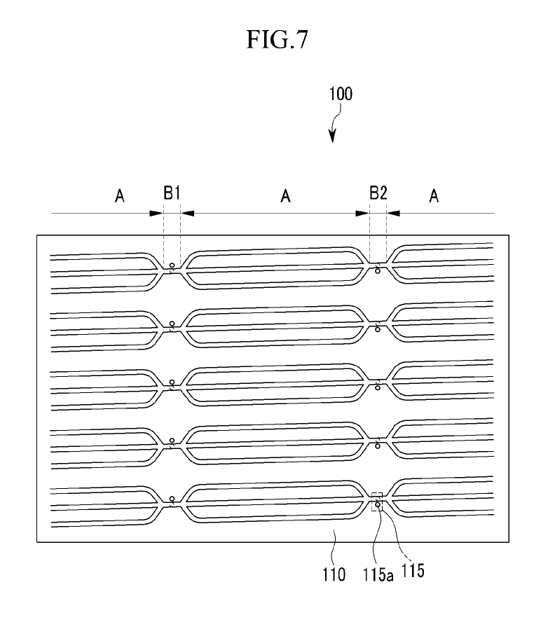

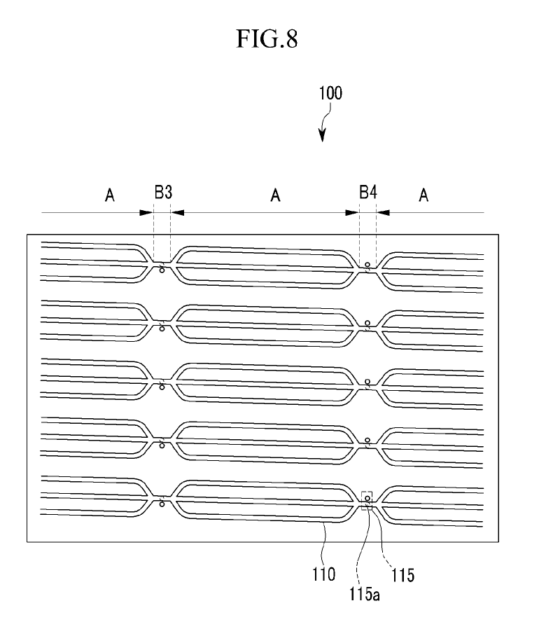

FIGS. 7 and 8 show misalignment between electrodes and contact holes of a semiconductor substrate due to a slanting front electrode.

Referring to FIG. 7, when the front electrode 120 is arranged in a right-upward slant on the semiconductor substrate 110, the left converged part B1 of front electrode 120 is overlapped with the contact hole 115a disposed at the second row of the contact hole group 115 and the right converged part B2 of front electrode 120 is overlapped with the contact hole 115a disposed at the first row of the contact hole group 115. Here, first and second rows refer to upper and lower of the pair of contact holes 115 (as defined along the y-axis of the plan views of FIGS. 7 and 8) coinciding at each overlap with part B1 of front electrode 120. In other words, the front electrode 120 may be overlapped with any one among contact holes 115a of the contact hole group 115 even when the front electrode 120 and the contact holes 115a are misaligned, so it is possible to prevent a contact failure between the front electrode 120 and the bus bar electrode 150 through the contact holes 115a.

Similarly, as shown in FIG. 8, when the front electrode 120 is arranged in a left-upward slant on the semiconductor substrate 110, the left converged part B3 of the front electrode 120 is overlapped with the contact hole 115a disposed in the first row of the contact hole group 115 and the right converged part B4 of front electrode 120 is overlapped with the contact hole 115a disposed in the second row of the contact hole group 115. In other words, the front electrode 120 may be overlapped with any one among contact holes 115a of the contact hole group 115 even when the front electrode 120 and the contact hole 115a are misaligned, so it is possible to prevent a contact failure between the front electrode 120 and the bus bar electrode 150 through contact holes 115a.

As shown above, according to one embodiment, a plurality of contact holes 115a are gathered to provide a plurality of contact hole groups 115. Since the contact hole groups 115 include a plurality of contact holes 115a, even when the front electrode 120 is slanted at an angle instead of being arranged in parallel to one direction of the semiconductor substrate 110, it is arrayed at a contact hole 115a of the contact hole group 115. Since the front electrode 120 may connect to the bus bar electrode 150 through the contact hole 115a, a contact failure is prevented.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A solar cell comprising:
a semiconductor substrate having a plurality of contact holes penetrating from one surface to an opposing surface of the semiconductor substrate and comprising a part having a first conductive layer selected from p-type and n-type conductive layers and a part having a second conductive layer different from the first conductive layer and selected from a p-type conductive layer and an n-type conductive layer;
a first electrode formed on one surface of the semiconductor substrate and electrically connected with the part having the first conductive layer;
a second electrode formed on an opposing surface of the semiconductor substrate and electrically connected with the first electrode; and
a third electrode formed on the surface of the semiconductor substrate having the second electrode and electrically connected with the part having the second conductive layer of the semiconductor substrate,
wherein the plurality of contact holes form a contact hole group, and
the first electrode and the second electrode are connected through one or more contact holes of the contact hole group.

2. The solar cell of claim 1, wherein a plurality of the contact hole groups are arranged to form a matrix.

3. The solar cell of claim 1, wherein the first electrode comprises a part arranged in parallel with an adjacent part of the first electrode, and a converged part arranged to converge with the adjacent parts of the first electrode.

4. The solar cell of claim 3, wherein the first electrode contacts the second electrode at the converged part.

5. The solar cell of claim 3, wherein the converged part of the first electrode overlaps with one or more contact holes of a portion of a plurality of the contact hole groups.

6. The solar cell of claim 3, wherein the converged part of a plurality of first electrodes is where the plurality of adjacent parts of the first electrodes converge.

7. The solar cell of claim 1, wherein the second electrode fills in at least a portion of the contact holes of the contact hole group.

8. The solar cell of claim 1, wherein the second electrode comprises a bar part extending along one direction of a plane of the substrate, and
the plurality of contact hole groups are arranged to overlap the bar part of the second electrode.

9. The solar cell of claim 1, further comprising a dielectric layer disposed between opposing surfaces of the semiconductor substrate and the second electrode and third electrode and having a plurality of openings,
wherein the semiconductor substrate and the third electrode are electrically connected through the openings.

10. The solar cell of claim 9, wherein the dielectric layer is disposed on a side surface of the contact hole between the semiconductor substrate and the second electrode.

11. The solar cell of claim 1 wherein the plurality of contact holes is arranged to be regularly or intervally spaced along a straight line, along crossed straight lines, in circular patterns, or in a geometric pattern.

12. The solar cell of claim 1, wherein the surface of the semiconductor substrate having the first electrode is textured.

13. The solar cell of claim 12, wherein the surface of the semiconductor substrate is textured to have a honeycomb pattern or pyramid-shaped protrusions and depressions.

14. The solar cell of claim 3, wherein adjacent parts of the first electrode comprise straight lines, wavy lines, zigzag lines, crenellated lines, lines of varying width, or a combination thereof.

15. A solar cell comprising:
a semiconductor substrate having a plurality of contact holes penetrating from one surface to an opposing surface of the semiconductor substrate and comprising a part having a first conductive layer selected from p-type and n-type conductive layers and a part having a second conductive layer different from the first conductive layer and selected from a p-type conductive layer and an n-type conductive layer;
a first electrode formed on one surface of the semiconductor substrate and electrically connected with the part having the first conductive layer;
a second electrode formed on an opposing surface of the semiconductor substrate and electrically connected with the first electrode; and
a third electrode formed on the surface of the semiconductor substrate having the second electrode and electrically connected with the part having the second conductive layer of the semiconductor substrate,
wherein the plurality of contact holes form a contact hole group, and
the first electrode and the second electrode are connected through one or more contact holes of a portion of a plurality of contact hole groups,
wherein the connected first and second electrodes form where the first electrode and the contact hole group matrix are misaligned.
